(19) United States
(12) Patent Application Publication
(10) Pub. No.: US 2009/0189524 A1
(43) Pub. Date: Jul. 30, 2009

(54) PLASMA DISPLAY PANEL AND ITS MANUFACTURING METHOD

(76) Inventor: Hideki Harada, Miyazaki (JP)

Correspondence Address: MATTINGLY & MALUR, P.C., 1800 DIAGONAL ROAD, SUITE 370, ALEXANDRIA, VA, 22314, US

(21) Appl. No.: 12/304,362

(22) PCT Filed: Jul. 31, 2006
(86) PCT No.: PCT/JP2006/315154

§ 371 Date: Dec. 11, 2008

(51) Int. Cl. H01J 17/49; G03F 7/20

(52) U.S. Cl. 313/582; 430/313; 430/319

(57) ABSTRACT

by using mask patterns of the same shape for electrode formation, an electrode and a dielectric layer are patterned into the same shape so that it is possible to eliminate a positional shift between the electrode and the dielectric layer, and consequently to make discharge voltage between cells uniform. A plasma display panel includes a first substrate on which the electrode and the dielectric layer covering the electrode are formed and a second substrate bonded to the first substrate. The electrode and the dielectric layer are patterned into the same shape when viewed in a plan view by patterning an electrode film formed on the first substrate and a dielectric material layer formed on the electrode film by using mask patterns of the same shape for electrode formation. The patterning surface of the electrode is covered with an insulating film.

### TECHNICAL FIELD

This invention relates to a plasma display panel (hereinafter, referred to as “PDP”), and more specifically relates to a PDP of an AC-drive type in which electrodes are formed on a panel substrate, with the electrodes covered with a dielectric layer, and a method for manufacturing the same.

### BACKGROUND ART

A three-electrode surface-discharge-type PDP of an AC-drive type has been known as a PDP of this kind. This PDP has a structure in which a large number of display electrodes capable of providing a surface discharge are provided in a horizontal direction on an inner face of a first glass substrate which is to be a front face side, with the display electrodes being covered with a dielectric layer, while a large number of address electrodes used for selecting a light emitting cell are provided in a direction intersecting with the display electrodes on an inner face of a second glass substrate which is to be a back face side, with the address electrodes being covered with a dielectric layer, so that each of intersections between the display electrodes and the address electrodes forms one cell (unit light-emitting area).

The PDP is manufactured by using a process in which the first glass substrate and the second glass substrate, thus produced, are aligned face to face with each other, and peripheral portions of these two substrates are bonded and sealed with each other by a glass sealing material, with a discharge gas being enclosed inside thereof.

In this PDP, a display light emission is carried out by a surface discharge between the display electrodes. The dielectric layer is formed on this display electrodes, and a film thickness of this dielectric layer gives an influence to a panel light emission efficiency and a discharge voltage. More specifically, as the film thickness of the dielectric layer becomes thicker, an electrostatic capacity of the dielectric layer becomes smaller, and the panel light emission efficiency is improved; however, the discharge voltage between the electrodes becomes higher to cause a high load on a driving circuit. In contrast, as the film thickness of the dielectric layer is made thinner, the discharge voltage between the electrodes can be made lower; however, the electrostatic capacity of the dielectric layer becomes higher to cause degradation of the panel light emission efficiency.

Incidentally, the surface discharge between the electrodes disposed in parallel with the substrate is initiated from a side face in a width direction of the electrode and spreads over the entire electrode. Therefore, when the film thickness of the dielectric layer in the width direction of the electrode is made thinner, the discharge voltage can be lowered, and when the film thickness of the dielectric layer in a thickness direction is made thicker, the light emission efficiency can be improved.

With respect to a shape and the film thickness of this dielectric layer, various proposals have been given. For example, with respect to the film thickness of the dielectric layer, techniques for making the width of the electrode thinner than the thickness of the electrode have been known in Patent Document 1, Patent Document 2, Patent Document 3 and the like. In this technique, after an electrode has been formed by patterning a conductive film, a dielectric material layer is formed thereon, and by cutting the dielectric material layer, the dielectric layer in a width direction of the electrode is made thinner. In other words, the dielectric material layer is processed, while being position-adjusted to the electrode.

### Patent Document 1: JP-A No. 2005-5189

### Patent Document 2: JP-A No. 2003-234069

### Patent Document 3: JP-A No. 2000-123743

### DISCLOSURE OF THE INVENTION

### Problems to be Solved by the Invention

In the PDP, it is necessary to provide a uniform discharge voltage between cells inside a panel. For this reason, the film thickness of the dielectric layer within the panel face needs to be made uniform. However, in the case where the dielectric material layer is processed, while being position-adjusted to the electrode as described above, a positional shift tends to occur between the electrode and a processed portion of the dielectric material layer, and deviations in the film thickness of the dielectric layer occur due to the positional shift, with the result that it becomes difficult to make the discharge voltage between cells uniform.

In view of the above state of the art, the present invention has been devised in which, by carrying out a patterning process using mask patterns of the same shape for electrode formation, an electrode and the dielectric layer are formed into the same shape so that it becomes possible to eliminate the positional shift between the electrode and the dielectric layer, and consequently to make the discharge voltage between cells uniform.

### Means to Solve the Problems

The present invention provides a plasma display panel comprising: a first substrate on which an electrode and a dielectric layer covering the electrode are formed; and a second substrate bonded to the first substrate, wherein the electrode and the dielectric layer are patterned into the same shape when viewed in a plan view by patterning an electrode film formed on the first substrate and a dielectric material layer formed on the electrode film by using mask patterns of the same shape for electrode formation, and the patterned surface of the electrode is covered with an insulating film.

### EFFECTS OF THE INVENTION

In accordance with the present invention, since the electrode and the dielectric layer are formed into the same shape by self-alignment (self align), with the patterning surface of the electrodes being covered with the insulating film, it is possible to eliminate deviations in film thicknesses between the dielectric layer and the insulating film that cover the electrodes, and consequently to make the discharge voltage between cells uniform.

### BRIEF DESCRIPTION OF THE DRAWINGS

FIGS. 1(a) and 1(b) are explanatory drawings that show a structure of a PDP in accordance with the present invention.

FIGS. 2(a) and 2(b) are explanatory drawings that show states of a frontside substrate and a backside substrate when viewed in a plan view.

FIGS. 3(a) and 3(b) are a plan view and a cross-sectional view of the PDP of the present invention.

FIG. 4 is a cross-sectional view showing a frontside substrate of embodiment 1 in accordance with the present invention.

FIG. 5 is a cross-sectional view showing a frontside substrate of embodiment 2 in accordance with the present invention.

FIG. 6 is a cross-sectional view showing a frontside substrate of embodiment 3 in accordance with the present invention.

FIGS. 7(a) to 7(h) are explanatory drawings that show a method for manufacturing the frontside substrate of embodiment 1 of the present invention.

FIGS. 8(a) to 8(h) are explanatory drawings that show another manufacturing method of embodiment 1 of the present invention.

FIGS. 9(a) to 9(h) are explanatory drawings that show a method for manufacturing the frontside substrate of embodiment 2 of the present invention.

FIGS. 10(a) to 10(c) are explanatory drawings that show a method for manufacturing the frontside substrate of embodiment 3 of the present invention.

### REFERENCE NUMERALS

10 PDP
11 Frontside substrate
12 Transparent electrode
12a Side face of transparent electrode
12c Transparent conductive film
13 Bus electrode
17a First dielectric layer
17b Second dielectric layer
17c First dielectric material layer
17d Photosensitive first dielectric material layer
18 Protective film
21 Backside Substrate
24 Dielectric layer
28R, 28G, 28B Phosphor layer
29 Lattice-shaped rib
30 Discharge space
31 Resist pattern
32 Void
A Address electrode
L Display line
X,Y Display electrode

### BEST MODE FOR CARRYING OUT THE INVENTION

In the present invention, examples of the first substrate and the second substrate include a substrate made of glass, quartz or ceramics and a substrate prepared by forming desired constituent elements, such as an electrode, an insulating film, a dielectric layer and a protective film, on such a substrate.

In accordance with the present invention, the electrode and the dielectric layer are formed into the same shape when viewed in a plan view by patterning the electrode film formed on the first substrate and the dielectric material layer formed thereon by using mask patterns of the same shape for electrode formation. Although any substrate may be used as the second substrate, normally, a substrate on which the address electrodes are formed in the direction intersecting with the electrodes is used.

The above electrode film may be formed by using various materials and methods conventionally known in the art. Examples of materials used for the electrode film include transparent conductive materials, such as ITO and SnO₂, and metal conductive materials, such as Ag, Au, Al, Cu and Cr. Various methods conventionally known in the art can be used for forming the electrode film. For example, a thick-film-forming technique such as printing may be used, or a thin-film-forming technique, such as a physical deposition method and a chemical deposition method, may be used for forming the electrode film. Examples of the thick-film-forming technique include a screen printing method and the like. In the thin-film-forming technique, examples of the physical deposition method include a vapor deposition method and a sputtering method. Examples of the chemical deposition method include a thermal CVD method and a photo CVD method, or a plasma CVD method.

The dielectric material layer may be formed in a manner so as to cover the electrode film by using any of various materials and methods known in the art. For example, a powder glass material or a photosensitive powder glass material may be used as a dielectric material used for the dielectric material layer. Moreover, a photosensitive heat-resistant resin material may be used.

Upon forming the dielectric material layer by using the powder glass material, for example, a glass paste, made from a glass powder (glass frit), a binder resin and a solvent, may be applied by using a screen printing method, or a green sheet (unsintered dielectric sheet) of the glass powder may be pasted to form the dielectric layer. As the glass powder, such as a ZnO—B₂O₅—Bi₂O₃-based low melting point glass, a ZnO—B₂O₅-alkali earth metal-based low melting point glass and a PbO—B₂O₅—SiO₂-based low melting point glass, may be used.

Moreover, upon forming the dielectric material layer by using the photosensitive powder glass material, for example, a photosensitive glass paste may be applied to the entire substrate, and dried to form the layer. Examples of the photosensitive glass paste includes materials formed by combining and mixing the glass powder, such as a ZnO—B₂O₅—Bi₂O₃-based low melting point glass, a ZnO—B₂O₅-alkali earth metal-based low melting point glass and a PbO—B₂O₅—SiO₂-based low melting point glass, with a vehicle material, such as an acrylic resin and an ethylcellulose resin, to which a photo radical initiator, a radical type photo polymerization initiator, a photo acid generator, an ionic photo acid generator, a photo cation polymerization initiator, or the like is added, or a photosensitive group having the same functions as these is applied.

Moreover, upon forming the dielectric material layer by using a photosensitive heat-resistant resin material, for example, a liquid-state or a sheet-shaped photosensitive heat-resistant resin material may be coated to the entire substrate by a known method, and patterned thereon by light irradiation to form the dielectric layer. Silicone (organic-silicon containing material), polyimide having a heat resistance of 400° C. or more and the like may be used as the photosensitive heat-resistant resin material.

Any insulating film may be used as long as it covers the patterning surface of the electrodes, and those films formed by using various known materials and methods in the art may be used. For example, the insulating film may be a protective film made from MgO formed by a vapor-phase film-forming method. Alternatively, the insulating film may be a protective film made of the dielectric film such as a SiO₂ film formed by the vaporphase film-forming method and MgO formed thereon. Moreover, it may be prepared as the dielectric film formed by the dielectric material fused upon firing the dielectric material layer.

With respect to the film thicknesses of the dielectric layer and the insulating film, the film thickness of the dielectric layer is desirably made thicker than the film thickness of the insulating layer.

In another aspect, the present invention relates to a method for manufacturing a plasma display panel that includes steps in which, after the electrode film has been formed on the first substrate configuring a panel, a photosensitive dielectric material layer is formed thereon, and by patterning the electrode film and the dielectric material layer by use of mask patterns of the same shape for electrode formation, the electrode and the dielectric layer are formed into the same shape when viewed in the plan view, with the patterning surface of the electrodes being covered with the insulating film.

In still another aspect, the present invention relates to a method for manufacturing a plasma display panel that includes steps in which, after the electrode film has been formed on the first substrate configuring a panel, the photosensitive dielectric material layer is formed thereon, and by patterning the photosensitive dielectric material layer by use of a mask pattern for electrode formation, the dielectric layer is formed, and then, by etching the electrode film by use of the patterned dielectric layer as a mask, the electrode is formed, with the etched face of the electrode being covered with the insulating film.

Hereinafter, the present invention will be described in detail by means of embodiments referring to Figs. Here, the present invention is not intended to be limited by these, and various modifications may be made therein.

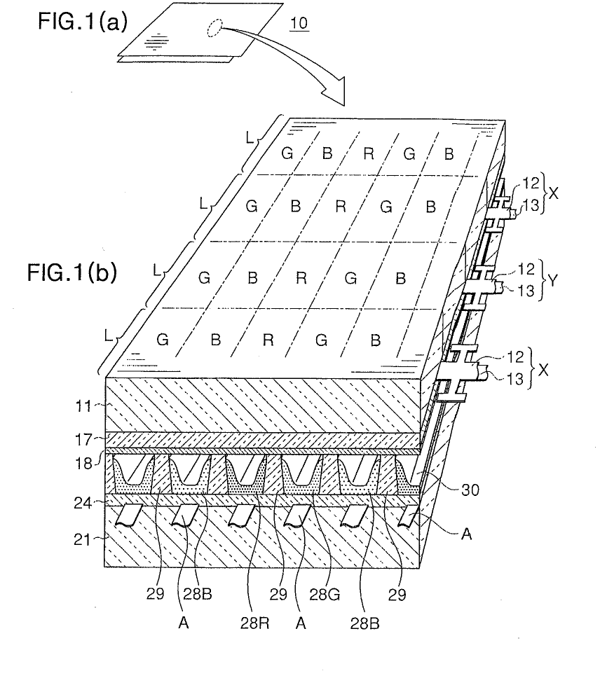

FIGS. 1(a) and 1(b) are explanatory drawings that show the structure of the PDP of the present invention. FIG. 1(a) is a general view, and FIG. 1(b) is a partially exploded perspective view. This PDP is a three-electrode surface-discharge-type PDP of an AC-drive type for a color display.

A PDP 10 is configured by a frontside substrate 11 on which constituent elements having functions as the PDP are formed, and a backside substrate 21. As the frontside substrate 11 and the backside substrate 21, for example, the glass substrate is used; however, in addition to the glass substrate, a quartz substrate, a ceramic substrate or the like may be used.

On an inner side face of the frontside substrate 11, a plurality of display electrodes X and display electrodes Y, which are extended in a longitudinal direction of a rectangular substrate, are disposed with equal intervals. All gaps between the adjacent display electrodes X and display electrodes Y form display lines L. Each of the display electrodes X and Y is configured by a transparent electrode 12 having a wide width, made of ITO, SnO₂ or the like, and a bus electrode 13 having a narrow width, made of metal, for example, Ag, Au, Al, Cu, and Cr, as well as a laminated body (for example, Cr/Cu/Cr laminated structure) thereof or the like. Upon forming display electrodes X and Y, the thick-film-forming technique such as the screen printing process is used for Ag and Au, and the thin-film-forming technique, such as the vapor deposition method and the sputtering method, and sandblasting and etching techniques are used for the other materials so that a desired number of electrodes having a desired thickness, width and gap can be formed.

Here, in the present PDP, a PDP having a so-called ALIS structure in which the display electrodes X and the display electrodes Y are placed with equal intervals, with each gap between the adjacent display electrode X and display electrode Y being allowed to form a display line L, has been exemplified; however, the present invention may also be applied to a PDP having a structure in which paired display electrodes X and Y are placed separately with a distance (non-discharge gap) in which no discharge is generated.

On the display electrodes X and Y, a dielectric layer 17 is formed in a manner so as to cover the display electrodes X and Y. The dielectric layer 17 has a two-layer structure including a first dielectric layer and a second dielectric layer.

A protective film 18, used for protecting the dielectric layer 17 from damage due to collision of ions generated by discharge upon displaying, is formed on the dielectric layer 17. This protective film is made from MgO. The protective film may be formed by using a known thin-film forming process in the art, such as an electron beam vapor deposition method and the sputtering method.

On the inner side face of the backside substrate 21, a plurality of address electrodes A are formed in a direction intersecting with the display electrodes X and Y when viewed on the plan view, and a dielectric layer 24 is formed in a manner so as to cover the address electrodes A. The address electrodes A generate an address discharge used for selecting cells to emit light at intersections with the display electrodes Y, and are formed into a three-layer structure of Cr/Cu/Cr. These address electrodes A may also be formed by using other materials, such as Ag, Au, Al, Cu and Cr. In the same manner as in the display electrodes X and Y, upon forming these address electrodes A, the thick-film-forming technique such as the screen printing process is used for Ag and Au, and the thin-film-forming technique, such as the vapor deposition method and the sputtering method, and the etching technique are used for the other materials so that a desired number of electrodes having desired thickness, width and gap can be formed. The dielectric layer 24 may be formed by using the same materials and the same methods as those for the dielectric layer 17.

Lattice-shaped ribs 29, used for separating the discharge space for each cell, are formed on the dielectric layer 24 between the adjacent address electrodes A. The lattice-shaped ribs 29 are also referred to as box ribs, mesh-shaped ribs, waffle ribs and the like. The ribs 29 may be formed by using a sand blasting method, a photo-etching method or the like. For example, in the sand blasting method, a glass paste, made from the glass frit, the binder resin, the solvent and the like, is applied onto a dielectric layer 24, and after the glass paste has been dried, cutting particles are blasted onto a resulting glass paste layer, with a cutting mask having apertures of a rib pattern being placed thereon, so that the glass paste layer exposed to the mask apertures is cut, and a resulting substrate is then fired; thus, the ribs are formed. Moreover, in the photo-etching method, in place of cutting by using the cutting particles, a photosensitive resin is used as the binder resin, and after exposing and developing processes by use of a mask, the resulting substrate is fired so that the ribs are formed.

On side faces and a bottom face of a cell having a rectangular shape surrounded by the lattice-shaped ribs 29, phosphor layers 28R, 28G and 28B corresponding to red (R), green (G) and blue (B) are formed. The phosphor layers 28R, 28G and 28B are formed through processes in which a phosphor paste containing a phosphor powder, a binder resin and a solvent is applied onto inside of a cell surrounded by the ribs 29 by using the screen printing method or a method using a dispenser, and after these processes have been repeated for each of the colors, a firing process is carried out thereon. These phosphor layers 28R, 28G and 28B may also be formed by using a photolithographic technique in which a sheet-shaped phosphor layer material (so-called green sheet) containing the phosphor powder, the photosensitive material and the binder resin is used. In this case, a sheet having a desired color may be affixed onto an entire face of a display area on the substrate, and the sheet is subjected to exposing and developing processes; thus, by repeating these processes for each of the colors, the phosphor layers having the respective colors are formed in the corresponding cell.

The PDP is manufactured through processes in which the frontside substrate 11 and the backside substrate 21 are aligned face to face with each other in a manner so as to allow the display electrodes X, Y and the address electrodes A to intersect with each other, and a peripheral portion thereof is sealed, with a discharge space 30 surrounded by the ribs 29 being filled with a discharge gas formed by mixing Xe and Ne. In this PDP, the discharge space 30 at each of intersections between the display electrodes X, Y and the address electrodes A forms one cell (unit light-emitting area) that is a minimum unit of a display. One pixel is configured by three cells of R, B and G.

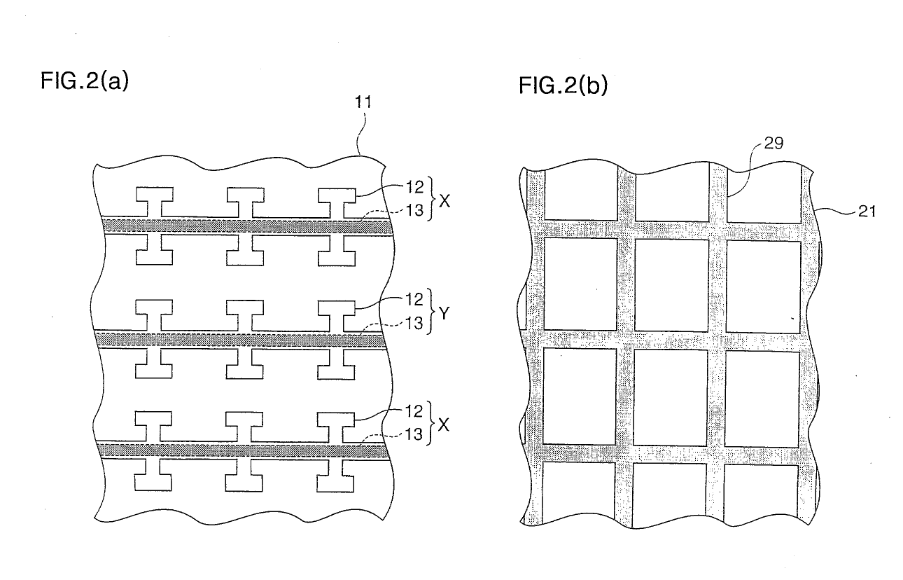

FIGS. 2(a) and 2(b) are explanatory drawings that show states of a frontside substrate and a backside substrate when viewed in the plan view. FIG. 2(a) shows the frontside substrate, and FIG. 2(b) shows the backside substrate.

A plurality of the display electrodes X and Y in parallel with one another are formed on the frontside substrate 11. Each of the display electrodes X and Y is configured by the transparent electrode 12 and the bus electrode 13. The transparent electrode 12 is configured by a base portion that extends laterally and a T-letter-shaped protruding portion that protrudes from the base portion. The lattice-shaped ribs 29 including longitudinal ribs and lateral ribs and the address electrodes A are formed on the backside substrate 21. In an area surrounded by the ribs 29, the phosphor layer (not shown) is formed. Here, in addition to the T-letter shape, a ladder shape, a stripe shape and the like may be used as a shape of the transparent electrode.

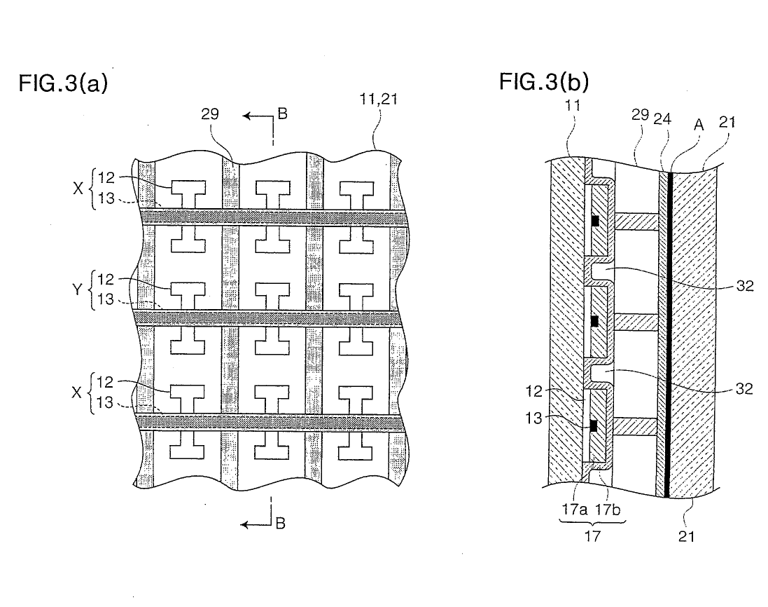

FIGS. 3(a) and 3(b) are a plan view and a cross-sectional view of the PDP. FIG. 3(a) shows a state in which the frontside substrate and the backside substrate are bonded to each other, and FIG. 3(b) shows a B-B line cross section of FIG. 3(a).

When the PDP is viewed in the plan view, the base portion of the transparent electrode 12 is superposed on the lateral rib, with the protruding portion of the transparent electrode 12 being positioned between the longitudinal ribs.

The dielectric layer 17 on the frontside substrate 11 is formed by a first dielectric layer 17a made from a glass material and a second dielectric layer 17b that is a SiO₂ film (insulating film) formed by the vapor-phase film-forming method. When the frontside substrate 11 and the backside substrate 21 are bonded to each other, voids 32 that communicate with each other in a row direction (extending direction of the display electrodes) are formed. These voids 32 form ventilation passages that are used for discharging an impurity gas from a discharge space of the PDP, and for injecting the discharge gas into the display space.

That is, upon forming the PDP, after the frontside substrate and the backside substrate have been produced, the two substrates are superposed on each other, with the peripheral portion being bonded to each other to be sealed, and in this sealing/bonding process, the impurity gas is discharged from the discharge space inside the PDP, and the discharge gas is enclosed therein. However, since the PDP of the box rib structure is a closed-type rib structure, the ventilation conductance inside the panel is small, in comparison with a PDP of the stripe rib structure, making it difficult to exhaust this impurity gas. For this reason, removal of the impurity gas becomes insufficient, with a result that panel display irregularities tend to occur. However, in the case where the frontside substrate 11 having the above structure is used, even upon combination with the backside substrate 21 on which the box ribs are formed, the exhausting process of the impurity gas and the filling process of the discharge gas can be sufficiently carried out by using the voids 32 that are communicated with each other in the row direction.

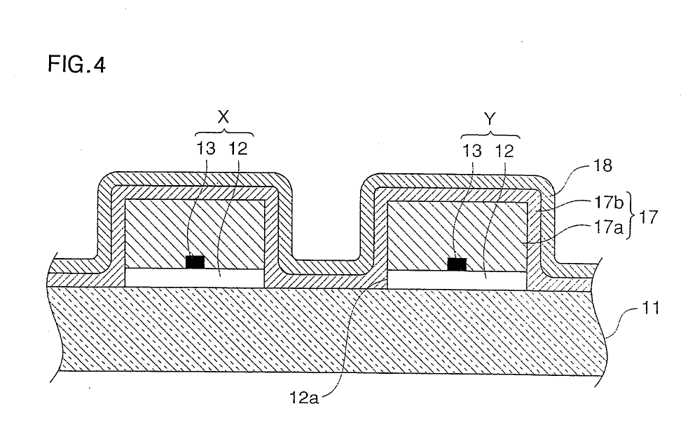

FIG. 4 is a cross-sectional view that shows the frontside substrate of embodiment 1.

On the frontside substrate 11, the display electrodes X and Y, each of which is configured by the transparent electrode 12 and the bus electrode 13, are formed, and the first dielectric layer 17a is formed on the transparent electrode 12 and the bus electrode 13 by using the glass material or the heat resistant resin material. This first dielectric layer 17a has the same shape as that of the transparent electrode 12, when the PDP is viewed in the plan view. The transparent electrode 12 and the first dielectric layer 17a are covered with the second dielectric layer 17b made of the SiO₂ film. A protective film 18, made from MgO, is formed on the second dielectric layer 17b.

In this manner, the dielectric layer 17 has the two-layer structure including the first dielectric layer 17a and the second dielectric layer 17b, and the entire dielectric layer has a structure in which the dielectric layer with a thick film is formed in the thickness direction of the electrode and the dielectric layer with a thin film is formed in the width direction of the electrode.

A side face 12a in a width direction of the transparent electrode 12 is covered only with the second dielectric layer 17b and the protective film 18. Since the second dielectric layer 17b and the protective film 18 are film-formed by using the vapor-phase film-forming method, they have a uniform thickness and are isotropically formed in accordance with a surface shape to be film-formed.

A discharge, generated between the display electrode X and the display electrode Y, is started between the side face 12a of a first transparent electrode and the side face 12a of a second adjacent transparent electrode, and this discharge is expanded over the entire of the first and the second transparent electrodes 12, however, since the side face 12a of the transparent electrode is covered with the second dielectric layer 17b having a uniform thickness as described above, the film thickness of the dielectric layer which defines the discharge voltage is made uniform among each cell so that the discharge voltages among the cells can be made uniform.

Moreover, since the first dielectric layer 17a having a thick film is formed in a thickness direction of the transparent electrode 12, its electrostatic capacity can be made sufficiently small so that the light-emitting efficiency of the PDP can be improved simultaneously.

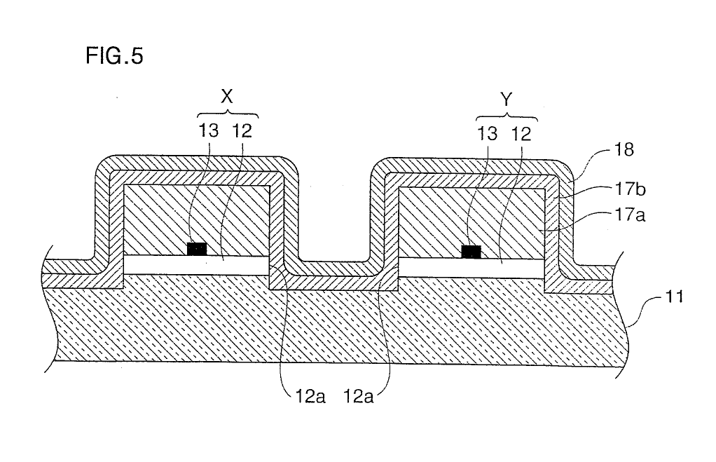

FIG. 5 is a cross-sectional view that shows the frontside substrate of embodiment 2.

In the present embodiment, a groove portion is formed between the transparent electrodes 12 on the frontside substrate 11. The other structures are the same as those in embodiment 1.

In the case where the groove portion is formed between the transparent electrodes 12 on the frontside substrate 11, since the side faces 12a of the transparent electrodes are mutually made face to face with the discharge space interposed therebetween, the discharge is started smoothly upon generating the discharge between the display electrodes X and Y, in comparison with the structure of embodiment 1.

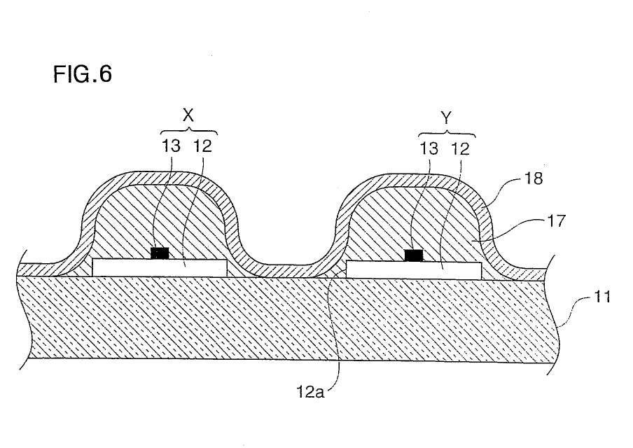

FIG. 6 is a cross-sectional view that shows the frontside substrate of embodiment 3.

In the present embodiment, the entire transparent electrode 12 and bus electrode 13 are covered with the dielectric layer 17. That is, a dielectric material layer made from the glass material is formed in a self-aligned state relative to the transparent electrode 12, and this dielectric material layer is fused when fired so as to cover the side face 12a of the transparent electrode. The protective film made from MgO is formed on the dielectric layer 17.

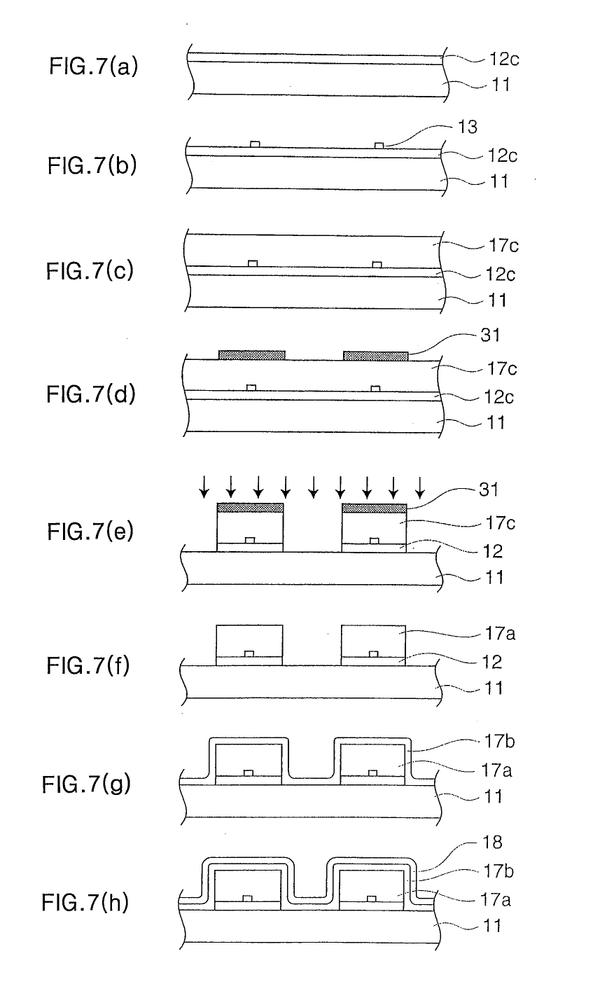

FIGS. 7(a) to 7(h) are explanatory drawings that show a method for manufacturing the frontside substrate of embodiment 1. This method relates to a method for manufacturing the first dielectric layer by using a glass material.

First, a transparent conductive film 12c serving as an electrode film is formed on a frontside glass substrate 11 with a thickness in a range from 0.1 to 0.2 μm (see FIG. 7(a)). This transparent conductive film 12c is formed by film-forming ITO, SnO₂ or the like on the entire glass substrate 11 by using the vapor deposition method, the sputtering method, or the like.

Next, the bus electrode 13 made of metal is formed on the transparent conductive film 12c with a thickness in a range from 2 to 4 μm (see FIG. 7(b)). This bus electrode 13 is formed through processes in which, after a metal mat film having three layers of Cr/Cu/Cr has been formed, a resist is applied thereto, and the resist is patterned by using exposing and developing processes, that is, by using a so-called photolithographic technique, and the metal mat film is etched by using the patterned resist as a mask.

Next, a first dielectric material layer 17c is formed thereon with a thickness in a range from 15 to 45 μm (see FIG. 7(c)). This first dielectric material layer 17c is formed by applying the glass paste made from the glass frit, the binder resin and the solvent to the entire substrate and drying the glass paste.

Next, a resist pattern 31 is formed on the first dielectric material layer 17c (see FIG. 7(d)). This resist pattern 31 is formed through processes in which the entire substrate is laminated with a photosensitive dry film resist, and the photosensitive dry film resist is patterned by using the photolithographic technique.

Next, a sandblasting process is carried out by blasting cutting particles in a direction indicated by an arrow in the drawing, with the resist pattern 31 serving as a mask so that the first dielectric material layer 17c and a transparent conductive film 12c are cut; thus, a cut pattern of the first dielectric material layer 17c and the transparent electrode 12 are formed (see FIG. 7(e)). With this process, the cut pattern of the first dielectric material layer 17c and the transparent electrode 12 are formed into the same shape when viewed in the plan view. Thereafter, the resist pattern 31 is peeled, and the resulting substrate is put into a heating chamber so that, by firing the cut pattern of the first dielectric material layer 17c, the first dielectric layer 17a is formed (see FIG. 7(f). Upon firing the cut pattern of the first dielectric material layer 17c, a firing process is carried out under such firing conditions that a shape of the first dielectric material layer 17c is not fused to collapse.

Next, the second dielectric layer 17b is formed on the entire glass substrate 11 having a thickness of about 5 μm in a manner so as to cover the first dielectric layer 17a. This second dielectric layer 17b is formed by film-forming the SiO₂ film by using the vapor-phase film-forming method such as the plasma CVD method (see FIG. 7(g)).

Next, the protective film 18 is formed on the second dielectric layer 17b having a film thickness of about 1 μm (FIG. 7(h)). This protective film 18 is formed by film-forming MgO by using the vapor-phase film-forming method, such as the vapor deposition method and the sputtering method (see FIG. 7(h)).

In the above method, after forming the first dielectric layer 17a, the second dielectric layer 17b and the protective film 18 are formed over the entire glass substrate 11. However, since the protective film 18 has a function as the dielectric layer, only the protective film 18 may be formed instead of forming the second dielectric layer 17b and the protective film 18. In this case, in order to allow the protective film 18 to function as the dielectric layer, the film thickness of the protective film 18 is made slightly thicker so as to have a thickness in a range from 2 to 5 μm.

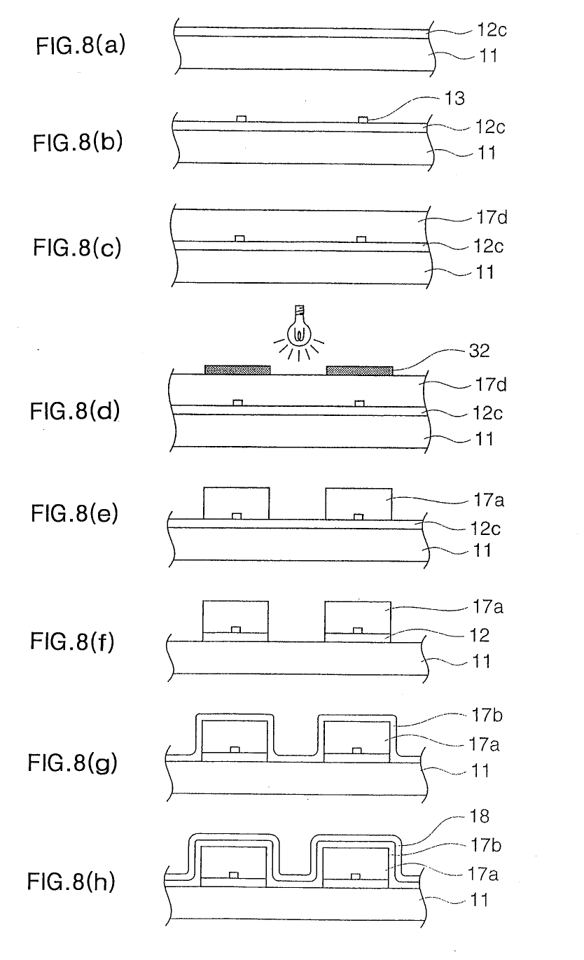

FIGS. 8(a) to 8(h) are explanatory drawings that show another manufacturing method of embodiment 1. This method relates to a manufacturing method for forming the first dielectric layer by using a photosensitive powder glass material or a photosensitive heat-resistant resin material.

In the present embodiment, the forming processes of the transparent conductive film 12c and the bus electrode 13 shown in FIGS. 8(a) and 8(b) are the same as those in FIGS. 7(a) and 7(b) in embodiment 1.

After forming of the transparent conductive film 12c and the bus electrode 13, a photosensitive first dielectric material layer 17d is formed by using the photosensitive powder glass material or the photosensitive heat resistant resin material (see FIG. 8(c)).

Upon forming the photosensitive first dielectric material layer 17d by using the photosensitive powder glass material, the photosensitive glass paste is applied to the entire substrate, and dried to form the layer. Examples of the photosensitive glass paste includes materials formed by combining and mixing glass powder, such as the ZnO—B₂O₅—Bi₂O₃-based lowmeltingpoint glass, the ZnO—B₂O₅-alkaliearthmetal-based lowmeltingpoint glass and the PbO—B₂O₅—SiO₂-based lowmeltingpoint glass, with the vehicle, such as the acrylic resin and the ethylcellulose resin, to which the photoradical initiator, the radicaltype photopolymerization initiator, the photoacid generator, the ionic photoacid generator, the photocation polymerization initiator, or the like is added, or the photosensitive group having the same functions as these is applied.

Moreover, upon forming the photosensitive dielectric material layer 17d by using the photosensitive heat-resistant resin material, for example, the liquid-state or the sheet-shaped photosensitive heat-resistant resin material is coated to the entire substrate by a known coating method, and patterned thereon by light irradiation to form the dielectric layer. Silicone (organic-silicon containing material), polyimide having a heat resistance of 400° C. or more and the like are used as the photosensitive heat-resistant resin material.

Next, a photo-mask 32 is disposed on the photosensitive first dielectric material layer 17d, and the photosensitive first dielectric material layer 17d is exposed (see FIG. 8(d)).

Next, the photosensitive first dielectric material layer 17d is developed to remove unnecessary portions so that a developed pattern of the first dielectric material layer 17d is formed. In the case where the photosensitive powder glass material is used as the photosensitive first dielectric material layer 17d, this is then put into a heating chamber in which the developed pattern of the first dielectric material layer 17d is fired so that the first dielectric layer 17a is formed (see FIG. 8(e)). In the case where the photosensitive heat-resistant resin material is used as the photosensitive first dielectric material layer 17d, the firing process is not executed.

Next, the transparent conductive film 12c is etched by using the first dielectric layer 17a as a mask so that transparent electrodes 12 are formed (see FIG. 8(f)). Thus, the first dielectric layer 17a and the transparent electrode 12 are formed into the same shape when viewed in the plan view.

The succeeding processes for forming the second dielectric layer 17b (see FIG. 8(g)) and the protective film 18 (see FIG. 8(h)) are the same as those in FIGS. 7(g) and 7(h).

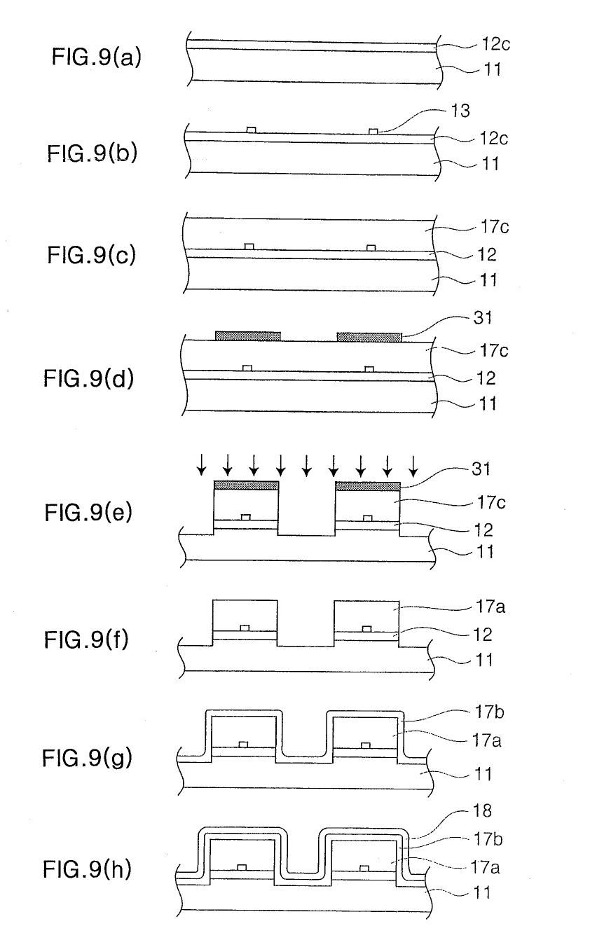

FIGS. 9(a) to 9(h) are explanatory drawings that show a manufacturing method for the frontside substrate of embodiment 2.

In the present embodiment, forming processes of the transparent dielectric film 12c, the bus electrode 13, the first dielectric material layer 17c and the resist pattern 31 shown in FIGS. 9(a) to 9(d) are the same as those in FIGS. 7(a) to 7(d) in embodiment 1.

In the present embodiment, upon cutting the first dielectric material layer 17c and the transparent conductive film 12c by blasting cutting particles in a direction of an arrow in the drawing with the resist pattern 31 serving as a mask and using a sandblasting method, the glass substrate 11 is also grooved (see FIG. 9(e)) to a predetermined depth. Thus, the cut pattern of the first dielectric material layer 17c and the transparent electrode 12 are formed into the same shape when viewed in the plan view, and the surface of the glass substrate 11 is also grooved into the same pattern as the cut pattern of the first dielectric material layer 17c and the transparent electrode 12, when viewed in the plan view.

The succeeding processes for peeling the resist pattern 31, forming the cut pattern of the first dielectric material layer 17c (see FIG. 9(f)), forming the second dielectric layer 17b (see FIG. 9(g)) and forming the protective film 18 (see FIG. 9(h)) are the same as those in FIGS. 7(f) to 7(h) of embodiment 1.

In the above processes, the first dielectric material layer 17c is fired after having been cut by sandblasting, however, a cutting process by the sandblasting may be carried out after a firing process.

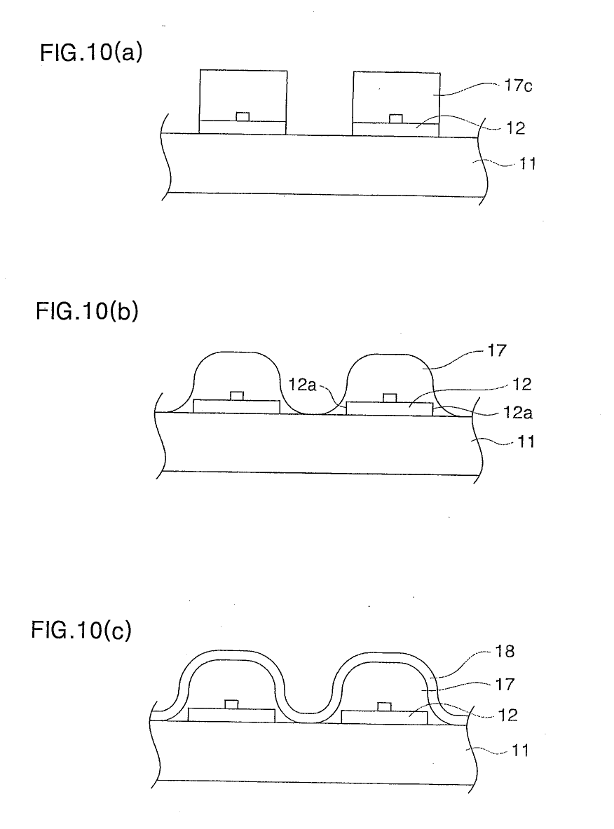

FIGS. 10(a) to 10(c) are explanatory drawings that show a manufacturing method for the frontside substrate of embodiment 3.

In the present embodiment, a state shown in FIG. 10(a) is the same as the state shown in FIG. 7(f) in embodiment 1. However, the cut pattern of the first dielectric material layer 17c is left unfired. That is, by cutting the first dielectric material layer 17c and the transparent conductive film 12c by sandblasting, the cut pattern of the first dielectric material layer 17c and the transparent electrode 12 are formed, with the resist pattern 31 having been peeled.

Thereafter, in this embodiment, the cut pattern of the first dielectric material layer 17c is put into a heating chamber and fired so that the dielectric layer 17 is formed (see FIG. 10(b)). Upon carrying out this firing process, firing conditions are set in such a manner that the side face 12a in the width direction of the transparent electrode 12 is covered with a dielectric film derived from a fused dielectric material.

Next, the protective film 18 is formed on the dielectric layer 17 (see FIG. 10(c)). In the same manner as in the manufacturing methods of embodiment 1 and embodiment 2, this protective film 18 is formed by film-forming MgO by using the vapor-phase film-forming method such as the vapor deposition method and the sputtering method.

As described above, the dielectric layer in the width direction of the transparent electrode that gives an influence to the discharge voltage between the transparent electrodes is thinly formed with a constant thickness so that the dielectric layer in the thickness direction of the transparent electrode that gives an influence to the light emission efficiency can be thickly formed; thus, the discharge voltage of each cell is suppressed to a low level, while the discharge voltage is uniformly set, thereby making it possible to provide a plasma display panel with a high light emitting efficiency.

1. A plasma display panel comprising:
a first substrate on which an electrode and a dielectric layer covering the electrode are formed; and
a second substrate bonded to the first substrate,
wherein the electrode and the dielectric layer are patterned into the same shape when viewed in a plan view by patterning an electrode film formed on the first substrate and a dielectric material layer formed on the electrode film by using mask patterns of the same shape for electrode formation, and
the patterned surface of the electrode is covered with an insulating film.

2. The plasma display panel according to claim 1, wherein the dielectric layer has a film thickness which is thicker than a film thickness of the insulating film.

3. The plasma display panel according to claim 1, wherein the insulating film is a protective film made of MgO, or a dielectric film formed by a vapor-phase film-forming method and a protective film made of MgO formed on the dielectric film.

4. The plasma display panel according to claim 1, wherein the insulating film is a dielectric film formed by a dielectric material which is fused upon firing the dielectric material layer.

5. A method for manufacturing a plasma display panel comprising the steps of:
forming an electrode film on a first substrate configuring a panel, and then forming a dielectric material layer on the electrode film;
forming electrodes and dielectric layers into the same shape when viewed in a plan view by patterning the electrode film and the dielectric material layer by use of mask patterns of the same shape for electrode formation; and
covering the patterned surfaces of the electrodes with an insulating film.

6. A method for manufacturing a plasma display panel comprising the steps of:
forming an electrode film on a first substrate configuring a panel, and then forming a photosensitive dielectric material layer on the electrode film;
forming dielectric layers by patterning the photosensitive dielectric material layer by using a mask pattern for electrode formation; and
forming electrodes by etching the electrode film by using the patterned dielectric layers as a mask; and
covering the etched surfaces of the electrodes with an insulating film.
